(19) United States
(12) Patent Application Publication
(10) Pub. No.: US 2025/0359233 A1
(43) Pub. Date: Nov. 20, 2025

(54) METHOD FOR MANUFACTURING SEMICONDUCTOR STRUCTURE AND SEMICONDUCTOR STRUCTURE

(71) Applicant: CXMT Corporation, Hefei City (CN)

(72) Inventors: Yang HU, Hefei City (CN); Xiaopeng WU, Hefei City (CN); Guoquan LIU, Hefei City (CN); HUI LYU, Hefei City (CN)

(73) Assignee: CXMT Corporation, Hefei City (CN)

(21) Appl. No.: 18/968,059

(22) Filed: Dec. 4, 2024

Related U.S. Application Data
(63) Continuation of application No. PCT/CN2024/125580, filed on Oct. 17, 2024.

(30) Foreign Application Priority Data
May 17, 2024 (CN) 202410620780.3

(51) Int. Cl. H10D 62/17; H01L 21/762

(52) U.S. Cl. CPC H10D 62/292; H01L 21/76224

(57) ABSTRACT

Provided are a method for manufacturing a semiconductor structure and a semiconductor structure. The method includes: providing a substrate provided thereon with active pillars and isolation layers arranged at intervals along a first direction and extending along a second direction; forming first grooves exposing top surfaces and parts of side surfaces of the active pillars; forming a filling material layer exposing at least the top surfaces of the active pillars in the first grooves; forming a metal layer directly covering at least the top surfaces of the active pillars; forming conductive structures extending along a third direction on the active pillars; removing at least the filling material layer to expose the first grooves; depositing a first dielectric layer at least on the side surfaces of the first grooves to form second grooves; and forming a second dielectric layer filling the second grooves.

### CROSS-REFERENCE TO RELATED APPLICATIONS

The present disclosure is a continuation of International Patent Application No. PCT/CN2024/125580 filed on Oct. 17, 2024, which claims priority to Chinese Patent Application No. 202410620780.3 filed on May 17, 2024. The disclosures of the above-referenced applications are hereby incorporated by reference in their entirety.

### BACKGROUND

A dynamic random access memory (DRAM) is one of semiconductor memories. Compared with a static memory, the DRAM has the advantages of a simpler structure, a lower manufacturing cost, and a higher capacity density. With the development of the semiconductor industry, semiconductor devices are becoming highly integrated, i.e., miniaturized. For highly integrated semiconductor devices, vertical channel transistors (VCTs) are taking the place of planar channel transistors.

However, the situation of low performance and low yield of the semiconductor memory devices still exists in the manufacturing process of the vertical channel transistors, and how to improve the performance and yield of the semiconductor memory devices is a technical problem to be solved urgently at present.

### SUMMARY

Embodiments of the present disclosure relate to the technical field of semiconductors, and in particular to a method for manufacturing a semiconductor structure and a semiconductor structure.

Embodiments of the present disclosure provide a method for manufacturing a semiconductor structure and a semiconductor structure, which are at least beneficial to improving the performance and yield of the semiconductor structure.

According to some embodiments of the present disclosure, an aspect of the embodiments of the present disclosure provides a method for manufacturing a semiconductor structure, which includes:
providing a substrate, where the substrate is provided with active pillars and isolation layers arranged at intervals along a first direction, the active pillars and the isolation layers all extend along a second direction, the first direction is parallel to a surface of the substrate, the second direction is parallel to a thickness direction of the substrate, and the second direction is perpendicular to the first direction;
removing parts of the isolation layers to form first grooves, where the first grooves expose top surfaces and parts of side surfaces of the active pillars;
forming a filling material layer in the first grooves, where the filling material layer exposes at least the top surfaces of the active pillars;
forming a metal layer, where the metal layer directly covers at least the top surfaces of the active pillars;
performing a heat treatment to form conductive structures on the active pillars, respectively, where the conductive structures extend along a third direction, and the third direction is perpendicular to the first direction and the second direction;
removing at least the filling material layer to expose the first grooves;
depositing a first dielectric layer at least on side surfaces of the first grooves to form second grooves, where the first dielectric layer covers side surfaces and top surfaces of the conductive structures; and
forming a second dielectric layer, where the second grooves are filled with the second dielectric layer.

Another aspect of the embodiments of the present disclosure provides a semiconductor structure, which includes: a substrate, where the substrate is provided with active pillars and isolation layers arranged at intervals along a first direction, the active pillars and the isolation layers all extend along a second direction, the first direction is parallel to a surface of the substrate, the second direction is parallel to a thickness direction of the substrate, and the second direction is perpendicular to the first direction;
conductive structures respectively located on the active pillars and connected to the active pillars, where the conductive structures extend along a third direction, and the third direction is perpendicular to the first direction and the second direction;
first grooves, each of the first grooves being located between adjacent conductive structures;
second grooves respectively located in the first grooves;
a first dielectric layer located between the first grooves and the second grooves, the first dielectric layer covering at least side surfaces of the first grooves and covering side surfaces and part of top surfaces of the conductive structures; and a second dielectric layer filling the second grooves.

According to the method for manufacturing a semiconductor structure and the semiconductor structure provided by the embodiments of the present disclosure, firstly, parts of the isolation layers are removed to form first grooves exposing the top surfaces and parts of the side surfaces of the active pillars; then, a filling material layer at least exposing the top surfaces of the active pillars is formed in the first grooves; next, a metal layer directly covering at least the top surfaces of the active pillars is formed, a heat treatment is performed to form conductive structures on the active pillars, respectively, and then at least the filling material layer is removed to expose the first grooves; finally, a first dielectric layer and a second dielectric layer are formed. The steps of forming first grooves first, then forming a filling material layer in the first grooves, and then removing the filling material layer after forming the conductive structures, in one aspect, make it possible to both remove parts of the isolation layers to form the first grooves and use the conductive structures as a mask to prepare the bit line in the manufacturing method; in another aspect, the steps can also prevent the appearance of the conductive structure from being changed and avoid the damage to the top and the sidewalls of the conductive structure, that is, the finally formed conductive structure can be prevented from being thinned and rounded (i.e. necking) in appearance, so that the orthographic projection of the conductive structure on the surface of the substrate is square and the conductive structure has flat or nearly flat side surfaces in the thickness direction of the substrate (i.e., the appearance of the sidewalls of the conductive structure is vertical or nearly vertical). Therefore, the resistance of the conductive structure can be reduced, the performance of the conductive structure can be improved, and the yield of the semiconductor device can be improved.

### BRIEF DESCRIPTION OF THE DRAWINGS

One or more embodiments are exemplarily illustrated with reference to pictures in the corresponding drawings, and these exemplary illustrations are not to be construed as limiting the embodiments. Unless expressly stated otherwise, the pictures in the drawings do not constitute a proportion limitation. To more clearly illustrate the technical solutions in the embodiments of the present disclosure or the conventional technology, a brief introduction to the drawings required to be used in the embodiments is given hereinafter. It is evident that the drawings described hereinafter are merely some embodiments of the present disclosure. For those of ordinary skill in the art, other drawings may be further obtained based on these drawings without creative effort.

FIG. 1A is a first schematic diagram showing the structures in respective steps of a method for manufacturing a semiconductor structure in some implementations.

FIG. 1B is a second schematic diagram showing the structures in respective steps of a method for manufacturing a semiconductor structure in some implementations.

FIG. 1C is a third schematic diagram showing the structures in respective steps of a method for manufacturing a semiconductor structure in some implementations.

FIG. 1D is a fourth schematic diagram showing the structures in respective steps of a method for manufacturing a semiconductor structure in some implementations.

FIG. 1E is a fifth schematic diagram showing the structures in respective steps of a method for manufacturing a semiconductor structure in some implementations.

FIG. 1F is a sixth schematic diagram showing the structures in respective steps of a method for manufacturing a semiconductor structure in some implementations.

FIG. 1G shows a structural diagram of the semiconductor structure in some implementations.

FIG. 2 is a process flow diagram of the steps of a method for manufacturing a semiconductor structure of the present disclosure in an embodiment.

FIG. 3A is a first schematic diagram showing the structures in respective steps of a method for manufacturing a semiconductor structure of the present disclosure in an embodiment.

FIG. 3B is a second schematic diagram showing the structures in respective steps of a method for manufacturing a semiconductor structure of the present disclosure in an embodiment.

FIG. 3C is a third schematic diagram showing the structures in respective steps of a method for manufacturing a semiconductor structure of the present disclosure in an embodiment.

FIG. 3D is a fourth schematic diagram showing the structures in respective steps of a method for manufacturing a semiconductor structure of the present disclosure in an embodiment.

FIG. 3E is a fifth schematic diagram showing the structures in respective steps of a method for manufacturing a semiconductor structure of the present disclosure in an embodiment.

FIG. 3F is a sixth schematic diagram showing the structures in respective steps of a method for manufacturing a semiconductor structure of the present disclosure in an embodiment.

FIG. 3G is a seventh schematic diagram showing the structures in respective steps of a method for manufacturing a semiconductor structure of the present disclosure in an embodiment.

FIG. 3H is an eighth schematic diagram showing the structures in respective steps of a method for manufacturing a semiconductor structure of the present disclosure in an embodiment.

FIG. 3I is a nineth schematic diagram showing the structures in respective steps of a method for manufacturing a semiconductor structure of the present disclosure in an embodiment.

FIG. 3J is a tenth schematic diagram showing the structures in respective steps of a method for manufacturing a semiconductor structure of the present disclosure in an embodiment.

FIG. 3K is an eleventh schematic diagram showing the structures in respective steps of a method for manufacturing a semiconductor structure of the present disclosure in an embodiment.

FIG. 3L is a twelfth schematic diagram showing the structures in respective steps of a method for manufacturing a semiconductor structure of the present disclosure in an embodiment.

FIG. 3M shows a first schematic structural diagram of a semiconductor structure of the present disclosure in an embodiment

FIG. 3N shows a second schematic structural diagram of a semiconductor structure of the present disclosure in an embodiment;

FIG. 4A is a first schematic diagram showing the structures in respective steps of a method for manufacturing a semiconductor structure of the present disclosure in another embodiment.

FIG. 4B is a second schematic diagram showing the structures in respective steps of a method for manufacturing a semiconductor structure of the present disclosure in another embodiment.

FIG. 4C is a third schematic diagram showing the structures in respective steps of a method for manufacturing a semiconductor structure of the present disclosure in another embodiment.

FIG. 4D is a fourth schematic diagram showing the structures in respective steps of a method for manufacturing a semiconductor structure of the present disclosure in another embodiment.

FIG. 4E is a fifth schematic diagram showing the structures in respective steps of a method for manufacturing a semiconductor structure of the present disclosure in another embodiment.

FIG. 4F is a sixth schematic diagram showing the structures in respective steps of a method for manufacturing a semiconductor structure of the present disclosure in another embodiment.

FIG. 4G is a seventh schematic diagram showing the structures in respective steps of a method for manufacturing a semiconductor structure of the present disclosure in another embodiment.

FIG. 4H is an eighth schematic diagram showing the structures in respective steps of a method for manufacturing a semiconductor structure of the present disclosure in another embodiment.

FIG. 4I is a nineth schematic diagram showing the structures in respective steps of a method for manufacturing a semiconductor structure of the present disclosure in another embodiment.

FIG. 4J is a tenth schematic diagram showing the structures in respective steps of a method for manufacturing a semiconductor structure of the present disclosure in another embodiment.

FIG. 4K shows a first schematic structural diagram of a semiconductor structure of the present disclosure in another embodiment.

FIG. 4L shows a second schematic structural diagram of a semiconductor structure of the present disclosure in another embodiment.

FIG. 5 is a schematic structural diagram of a semiconductor structure of the present disclosure in another embodiment.

FIG. 6 is a schematic structural diagram of a memory device formed by bonding the wafer having the semiconductor structure of the present disclosure to one wafer.

FIG. 7 is a schematic structural diagram of a memory device formed by bonding the wafer having the semiconductor structure of the present disclosure to another wafer.

### DETAILED DESCRIPTION

The technical solutions of the present disclosure will be further elaborated below with reference to the drawings and embodiments. While exemplary implementations of the present disclosure are shown in the drawings, it should be understood that the present disclosure may be implemented in various forms and should not be limited by the implementations set forth herein. Rather, these implementations are provided so that the present disclosure will be more thoroughly understood and the scope of the present disclosure will be fully conveyed to those skilled in the art.

The present disclosure is more specifically described in the following paragraphs with reference to the drawings by way of example. Advantages and features of the present disclosure will become apparent from the following description and claims. It should be noted that the drawings are all in a very simplified form and not to precise scale, and are provided only for the purpose of facilitating a convenient and clear description of the embodiments of the present disclosure.

It will be understood that the meaning of “on”, “above”, and “over” in the present disclosure should be interpreted in the broadest manner such that “on” not only includes the meaning of “on” something with no intermediate feature or layer therebetween (i.e., directly on something) but also includes the meaning of “on” something with an intermediate feature or a layer therebetween.

In the embodiments of the present disclosure, the terms “first”, “second”, “third”, and the like are used for distinguishing similar objects and are not necessarily used for describing a particular order or sequence.

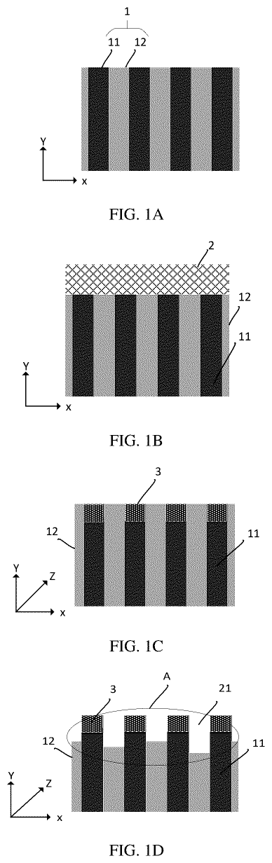

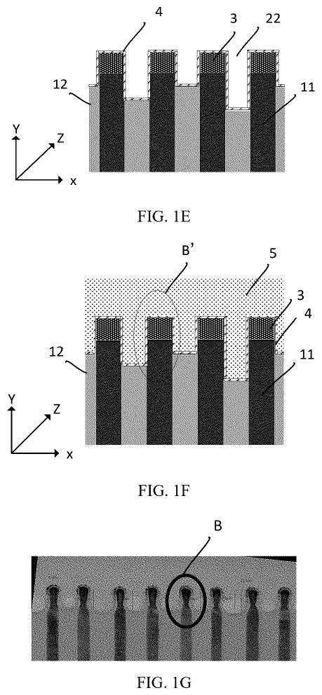

As shown in FIGS. 1A-1F, in a manufacturing process of a semiconductor device in some implementations, as shown in FIG. 1A, a substrate 1 has active pillars 11 and isolation layers 12 arranged at intervals along the first direction X, and the active pillars 11 and the isolation layers 12 all extend along the second direction Y; the first direction X is parallel to the surface of the substrate 1, the second direction Y is parallel to the thickness direction of the substrate 1, and the second direction Y is perpendicular to the first direction X. After the active pillars 11 and the isolation layers 12 are processed to be flush with each other, as shown in FIG. 1B, a metal layer 2 is formed on the active pillars 11 and the isolation layers 12, and after heat treatment, conductive structures 3 are respectively formed on the active pillars 11 as shown in FIG. 1C (in an implementation, the material of the metal layer 2 may be Ni doped with Pt (NiPt); Ni is diffused into the Si lattices of the active pillars 11 during heat treatment, NiSi is formed after Ni is doped into the Si lattices and it forms the conductive structures 3 (the conductive structures 3 extend along the third direction Z, and the third direction Z is perpendicular to the first direction X and the second direction Y), and the remaining metal layer is removed by acid cleaning, thus obtaining the structure shown in FIG. 1C); next, as shown in FIG. 1D, a wet etching process (such as a Certas process) is performed to etch back part of each isolation layer 12 to form first trenches 21. During the wet etching, under the action of the mixed gas composed of the HF gas, the water vapor, and the carrier gas (such as nitrogen or argon), HF reacts with the isolation layer 12 (such as silicon oxide in the isolation layer 12) to etch back part of the isolation layer 12; since HF reacts with Ni at the same time and thereby causes a change in the appearance of the conductive structure 3, i.e., HF causes damage to the top and sidewalls of the conductive structures 3, the conductive structures 3 appears to be thinned and rounded (i.e., necking), so that the originally thick bit lines becomes thinned and loses flat side surfaces in the second direction Y, and thus the resistance of the bit line itself increases and, correspondingly, the first trench 21 also loses the flat side surface in the second direction Y; meanwhile, the presence of HF and oxygen may change Ni dissipated from the conductive structure 3 into nickel oxide, which can prevent the etching back of the isolation layer 12, so that the height of back etching of adjacent isolation layers 12 is not uniform, and the top surface of the isolation layer 12 after etching back in the first direction X is not flat (U-shaped or V-shaped, not shown in FIG. 1D, but specifically see FIG. 1G for details), accordingly, in the first direction X, the first trench 21 loses the flat bottom surface (the bottom surface is U-shaped or V-shaped, not shown in FIG. 1D, but see FIG. 1G) and the height of the bottom surfaces of adjacent first trenches 21 is not the same. For the appearance of this part, reference may specifically be made to the structure A in FIG. 1D, and reference may also be specifically made to the semiconductor structure shown in FIG. 1G for the structure A. As shown in FIG. 1E, a first dielectric layer 4 is conformally deposited in the first trench 21 after the conductive structure 3 is formed, and a second groove 22 is formed, where the first dielectric layer 4 covers the side surfaces and the top surface of the conductive structure 3 and the side surfaces and the bottom surface of the first trench 21. Finally, as shown in FIG. 1F, a second dielectric layer 5 filling the second groove 22 is formed, and reference may be specifically made to the semiconductor structure shown in FIG. 1G for the semiconductor structure shown in FIG. 1F, where the structure B′ in FIG. 1F corresponds to the structure B in FIG. 1G. In addition, in the semiconductor structure, the parasitic capacitance between the conductive structures 3 is relatively large due to the high dielectric constant of the first dielectric layer 4.

Therefore, the present disclosure provides a method for manufacturing a semiconductor structure and a semiconductor structure, which can protect the conductive structures from the defect of the reduction in terms of the appearance and reduce the resistance of the conductive structures and the parasitic capacitance between the conductive structures.

The embodiments of the present disclosure will be described in detail below with reference to the drawings. However, those of ordinary skill in the art can understand that in the embodiments of the present disclosure, numerous technical details are set forth to enable readers to better understand the present disclosure. However, the technical solutions claimed by the present disclosure can also be implemented even without these technical details and the various changes and modifications based on the following embodiments.

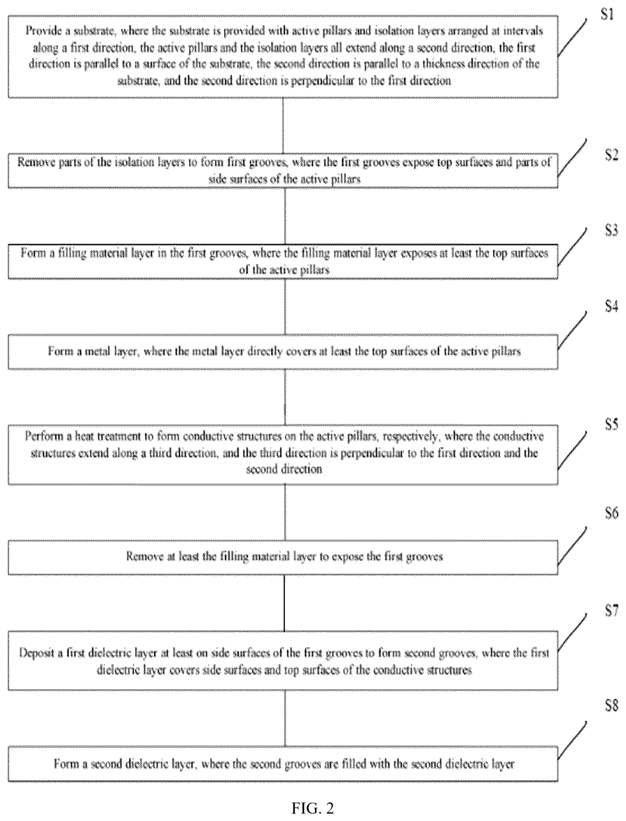

As shown in FIG. 2, the method for manufacturing a semiconductor structure of the present disclosure includes:
S1, providing a substrate, where the substrate is provided with active pillars and isolation layers arranged at intervals along the first direction, the active pillars and the isolation layers all extend along the second direction, the first direction is parallel to the surface of the substrate, the second direction is parallel to the thickness direction of the substrate, and the second direction is perpendicular to the first direction;
S2, removing parts of the isolation layers to form first grooves, where the first grooves expose top surfaces and parts of side surfaces of the active pillars;
S3, forming a filling material layer in the first grooves, where the filling material layer exposes at least the top surfaces of the active pillars;
S4, forming a metal layer, where the metal layer directly covers at least the top surfaces of the active pillars;
S5, performing a heat treatment to form conductive structures on the active pillars, respectively, where the conductive structures extend along the third direction, and the third direction is perpendicular to the first direction and the second direction;
S6, removing at least the filling material layer to expose the first grooves;
S7, depositing a first dielectric layer at least on side surfaces of the first grooves to form second grooves, where the first dielectric layer covers side surfaces and top surfaces of the conductive structures; and
S8, forming a second dielectric layer, where the second grooves are filled with the second dielectric layer.

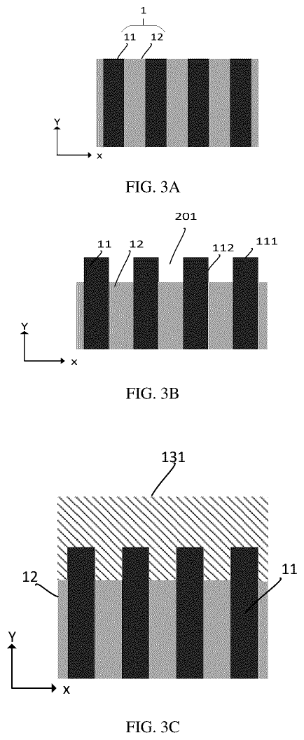

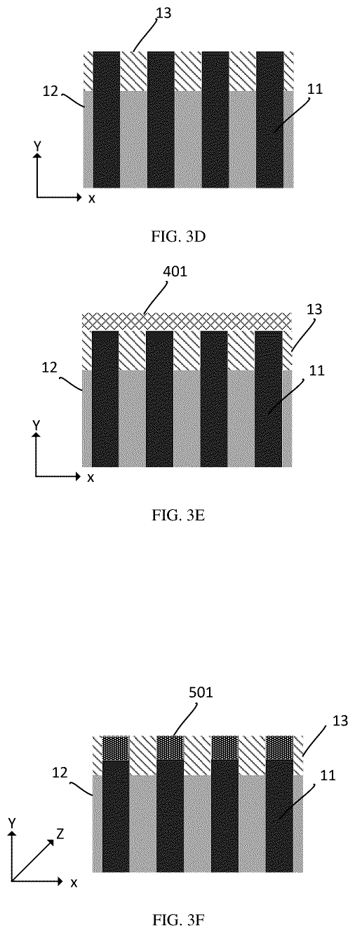

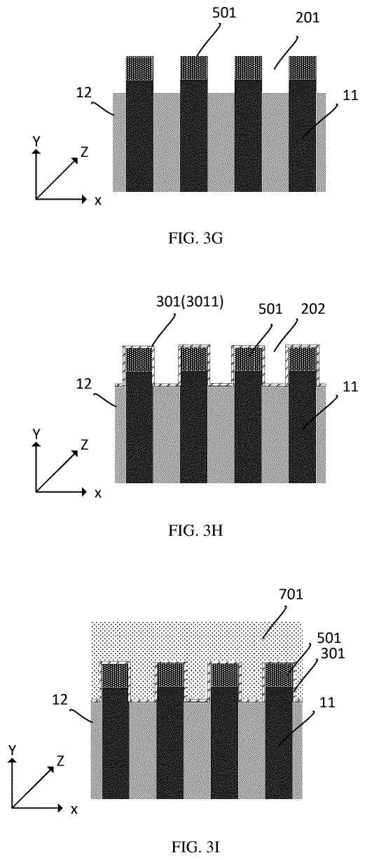

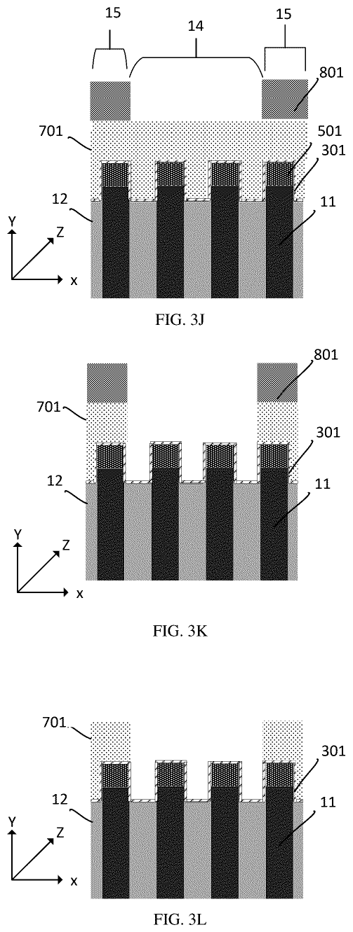

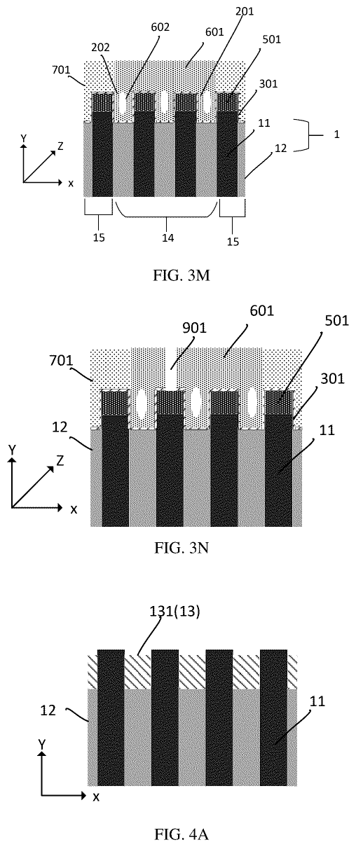

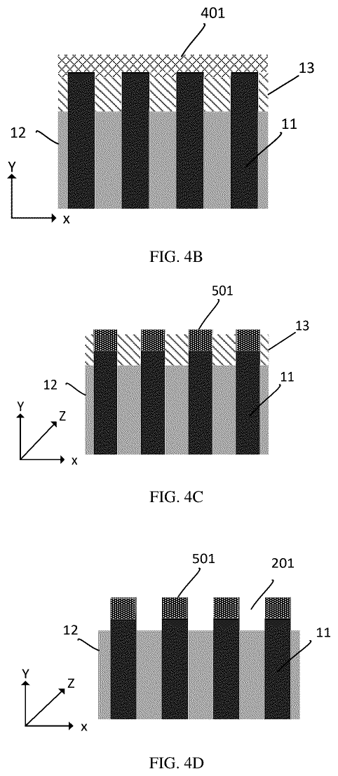

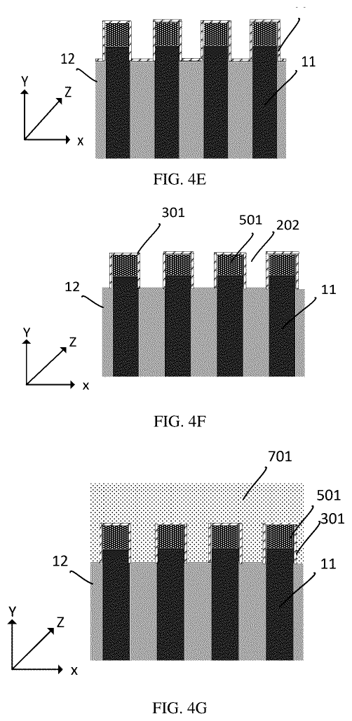

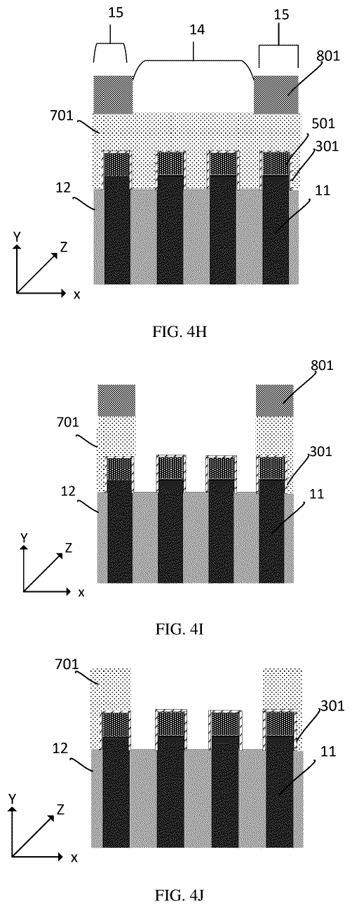

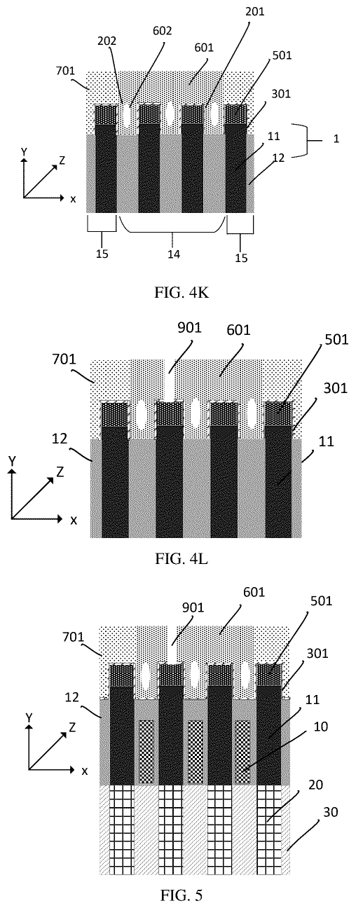

FIGS. 3A-3N are schematic diagrams showing the structures in respective steps of a method for manufacturing a semiconductor structure of the present disclosure in a specific implementation, where FIG. 3M and FIG. 3N each show a schematic structural diagram of a semiconductor structure of the present disclosure in a specific implementation. FIGS. 4A-4L are schematic diagrams showing the structures in respective steps of a method for manufacturing a semiconductor structure of the present disclosure in another specific implementation, where FIG. 4K and FIG. 4L each show a schematic structural diagram of a semiconductor structure of the present disclosure in another specific implementation. FIGS. 4A-4L are another specific implementation of corresponding steps of FIGS. 3C-3N. For example, FIG. 4A is another specific implementation of corresponding steps of FIGS. 3C-3D, FIG. 4B is another specific implementation of the corresponding step of FIG. 3E, and so on.

In an embodiment of the present disclosure, in step S1 of the method for manufacturing a semiconductor structure, as shown in FIG. 3A, a substrate 1 is provided, and the substrate 1 is provided with active pillars 11 and isolation layers 12 arranged at intervals along a first direction X. The active pillars 11 and the isolation layers 12 all extend along a second direction Y, the first direction X is parallel to the surface of the substrate 1, the second direction Y is parallel to the thickness direction of the substrate 1, and the second direction Y is perpendicular to the first direction X.

The material of the substrate may be silicon (Si), germanium (Ge), silicon germanium (GeSi), or silicon carbide (SiC), or may be silicon-on-insulator (SOI) or germanium-on-insulator (GOI), or may be other materials such as group III-V compounds, e.g., gallium arsenide. The material of the substrate in this embodiment is silicon. The substrate is doped with certain impurity ions as required, and the impurity ions may be N-typed impurity ions or P-typed impurity ions.

In an embodiment of the present disclosure, a method for forming the active pillars 11 is provided, and the method includes, but is not limited to, the following steps: forming a plurality of grooves in the substrate by adopting a photoetching method; filling the trenches with an isolation material to form an isolation layer 12, where the isolation material includes, but is not limited to, silicon oxide, silicon nitride, silicon oxynitride, or other suitable isolation materials. In this specific implementation, the isolation material is silicon oxide. The substrate isolated by the isolation layers 12 is the active pillars 11. In this specific implementation, as shown in FIG. 3A, the active pillars 11 and the isolation layers 12 are arranged at intervals along the first direction X parallel to the surface of the substrate 1, and the active pillars 11 and the isolation layers 12 all extend along the second direction Y parallel to the thickness direction of the substrate 1.

In an embodiment of the present disclosure, in step S2 of the method for manufacturing a semiconductor structure, as shown in FIG. 3B, a part of the isolation layer 12 is removed to form first grooves 201, and the first grooves 201 expose the top surfaces 111 and a part of the side surfaces 112 of the active pillars 11. It will be appreciated by those skilled in the art that in the step shown in FIG. 3B, the wet etching, such as a Certas process, may be performed. Under the action of the mixed gas composed of HF gas, water vapor, and carrier gas (such as nitrogen or argon), HF reacts with the isolation layer 12 (such as silicon oxide in the isolation layer 12) to etch back part of the isolation layer 12. Since the etching selectivity of HF for the isolation layer 12 (e.g., silicon oxide in the isolation layer 12) and the active pillar 11 (e.g., silicon in the active pillar 11) is very high (i.e., the active pillar 11 is not or substantially not etched when the isolation layer 12 is etched back), the height of the etching back of adjacent isolation layers 12 is uniform and the top surfaces of the isolation layers 12 in the first direction X after the etching back are flat or nearly flat, the active pillar 11 has flat or nearly flat side surfaces in the second direction Y (i.e., the appearance of the sidewalls of the active pillar is vertical or nearly vertical); accordingly, in the first direction X, the first groove 201 has a flat or nearly flat bottom surface (i.e., the bottom surface of the first groove is not U-shaped or V-shaped) and the heights of the bottom surfaces of adjacent first grooves 201 are the same, and in the second direction Y, the first groove 201 has flat or nearly flat side surfaces (i.e., the appearance of the first groove is vertical or nearly vertical).

In an embodiment of the present disclosure, the depth of the first groove 201 may be set according to specific process requirements, and in an implementation, as shown in FIG. 3B and FIG. 3G or as shown in FIG. 4D, in the second direction Y, the depth of the first groove 201 is greater than the thickness of the conductive structure 501.

In an embodiment of the present disclosure, in step S3 of the method for manufacturing a semiconductor structure, a filling material layer is formed in the first grooves, and the filling material layer exposes at least the top surfaces of the active pillars. It will be appreciated by those skilled in the art that the filling material layer at least exposing the top surfaces of the active pillars includes the fill material layer exposing the top surfaces of the active pillars and the fill material layer exposing the top surfaces and parts of the side surfaces of the active pillars. When the filling material layer also exposes a part of the side surfaces of the active pillar while exposing the top surfaces of the active pillars, the material of the metal layer may be diffused into the active pillars from the side surfaces of the active pillars during a subsequent thermal process to form the conductive structures.

In an implementation, to ensure that the conductive structure has a predetermined thickness, in the step of forming the filling material layer in the first grooves, in the second direction Y, the height of the top surface of the filling material layer is controlled to be not lower than the height at which 50% of the thickness of the conductive structure is present, and the filling material layer exposes the top surfaces of the active pillars.

In an implementation, the step of forming a filling material layer in the first grooves includes:
forming an initial filling material layer in the first grooves, where the first grooves are filled with the initial filling material layer and the initial filling material layer covers the top surfaces of the active pillars;
removing at least the initial filling material layer covering the top surfaces of the active pillars such that in the second direction, the height of the top surface of the initial filling material layer that remains is not lower than the height at which 50% of the thickness of the conductive structure is present, where the initial filling material layer that remains serves as the filling material layer; or
forming an initial filling material layer in the first grooves such that in the second direction, the height of the top surface of the initial filling material layer is not lower than the height at which 50% of the thickness of the conductive structure is present, and the initial filling material layer exposes the top surfaces of the active pillars, where the initial filling material layer serves as the filling material layer.

In an implementation, as shown in FIGS. 3C-3D, the step of forming the filling material layer 13 in the first grooves 201 includes:
as shown in FIG. 3C, forming an initial filling material layer 131 in the first grooves 201, where the first grooves 201 are filled with the initial filling material layer 131 and the initial filling material layer covers the top surfaces of the active pillars 11; and
as shown in FIG. 3D, removing at least the initial filling material layer 131 covering the top surfaces of the active pillars 11 such that in the second direction Y, the height of the top surface of the initial filling material layer 131 that remains is not lower than the height at which 50% of the thickness of the conductive structure 501 is present, where the initial filling material layer 131 that remains serves as the filling material layer 13.

In another implementation, as shown in FIG. 4A, the step of forming the filling material layer 13 in the first grooves 201 includes:
forming an initial filling material layer 131 in the first grooves 201, such that in the second direction Y, the height of the top surface of the initial filling material layer 131 is not lower than the height at which 50% of the thickness of the conductive structure 501 is present, and the initial filling material layer 131 exposes the top surfaces of the active pillars 11, where the initial filling material layer 131 serves as the filling material layer 13.

In an embodiment of the present disclosure, in step S4 of the method for manufacturing a semiconductor structure, a metal layer is formed, where the metal layer at least directly covers the top surfaces of the active pillars. It will be appreciated by those skilled in the art that the metal layer at least directly covering the top surfaces of the active pillars includes the metal layer directly covering the top surfaces of the active pillars and the metal layer directly covering the top surfaces and parts of the side surfaces of the active pillars. When the filling material layer exposes the top surfaces of the active pillars, the corresponding metal layer directly covers the top surfaces of the active pillars; when the filling material layer exposes the top surfaces of the active pillars and also exposes parts of the side surfaces of the active pillars, the corresponding metal layer directly covers the top surfaces and parts of the side surfaces of the active pillars.

Specific methods for forming the metal layer include one of an atomic layer deposition (ALD) process, a plasma enhanced atomic layer deposition (PEALD) process, a chemical vapor deposition (CVD) process, and a plasma enhanced chemical vapor deposition (PECVD) process. The metal layer includes, but is not limited to, the following materials: such as one or more of tungsten (W), ruthenium (Ru), iridium (Ir), tantalum (Ta), titanium (Ti), platinum (Pt), molybdenum (Mo), and nickel (Ni); the metal layer is preferably platinum-doped nickel (NiPt) in this embodiment, where the mass percentage of Pt in the platinum-doped nickel (NiPt) may be 5%-30%.

In an implementation, as shown in FIG. 3E, a metal layer 401 is formed, where the metal layer 401 directly covers the top surfaces of the active pillars 11.

In another implementation, as shown in FIG. 4B, a metal layer 401 is formed, where the metal layer 401 directly covers the top surfaces and parts of the side surfaces of the active pillars 11.

In the embodiment of the present disclosure, in step S5 of the method for manufacturing a semiconductor structure, as shown in FIG. 3F and FIG. 4C, a heat treatment is performed to form the conductive structures 501 on the active pillars 11, respectively, where the conductive structure 501 extends along the third direction Z, and the third direction Z is perpendicular to the first direction X and the second direction Y.

Specific processes for performing the heat treatment to form the conductive structures include, but are not limited to, the following methods: the heat treatment may be performed by the high-temperature rapid thermal processing (RTP) process. Through the RTP process, the metal (e.g., Pt in NiPt) in the metal layer is diffused into the Si lattice of the active pillar, and a metal silicide layer (e.g., NiSi) is formed after doping the Si lattice with the metal (e.g., Ni), and the metal silicide layer has a good electrical conductivity to form a conductive structure, which is electrically connected to the active pillar.

Specifically, the material of the conductive structure 501 may be one or more of titanium silicide (TiSi), tantalum silicide (TaSi), nickel silicide (NiSi), and cobalt silicide (CoSi), and preferably, the material of the conductive structure 501 is nickel silicide (NiSi), where the resistivity of NiSi is not more than 20 μΩ·cm, and the resistivity of NiSi2 is 24-30 μΩ·cm.

In an embodiment of the present disclosure, in step S6 of the method for manufacturing a semiconductor structure, as shown in FIG. 3G and FIG. 4D, at least the filling material layer is removed to expose the first grooves. It will be appreciated by those skilled in the art that removing at least the filling material layer includes: in the case of the structure shown in FIGS. 3E-3F, as shown in FIG. 3G, the first grooves 201 can be exposed by removing the filling material layer 13 and the remaining metal layer 401. In the case of the structure shown in FIGS. 4B-4C, as shown in FIG. 4D, the first grooves 201 can be exposed by removing the filling material layer 13 and the remaining metal layer 401.

After the conductive structures are formed, the remaining metal layer may be removed by acid cleaning, and due to the high removal selectivity, the formed conductive structures may not be damaged or destroyed in the acid cleaning process, so that the structures shown in FIG. 3F and FIG. 4C are obtained and the performance of the conductive structures 501 is improved.

In an embodiment of the present disclosure, in the step of removing the filling material layer, the etching selectivity of the filling material layer to the conductive structure is not less than 20. It will be appreciated that it is also satisfied that in the step of removing at least the filling material layer, the etching selectivity of the filling material layer to the active pillar is not less than 20, and the etching selectivity of the filling material layer to the isolation layer is not less than 20.

In an embodiment of the present disclosure, in the step of removing the filling material layer, since the etching selectivities of the filling material layer to the conductive structure, the active pillar, and the isolation layer are all large and not less than 20, when the filling material layer is removed, there will be no or substantially no etching or reaction of the formed conductive structures, the formed active pillars, and the formed isolation layer, that is, there will be no or substantially no destroy or damage to the formed conductive structures, the formed active pillars, and the formed isolation layer, so that the performance of the conductive structures can be improved. Therefore, as shown in FIG. 3G and FIG. 4D, the conductive structure 501 does not have an appearance characterized by a rounded top and a thinned waist, i.e., necking, that is, the orthographic projection of the conductive structure 501 on the surface of the substrate 1 is square; in the second direction Y, the conductive structure 501 has flat or nearly flat side surfaces (i.e., the sidewalls of the conductive structure 501 are vertical or nearly vertical). In the second direction Y, the first groove 201 exposed after removal of the filling material layer has flat or nearly flat side surface (i.e., the sidewalls of the first groove 201 are vertical or nearly vertical); in the first direction X, the first groove 201 exposed after removing the filling material layer has a flat or nearly flat bottom surface (no U-shaped or V-shaped bottom is present) and the heights of the bottom surfaces of adjacent first grooves 201 are the same or nearly the same.

Specifically, the material of the filling material layer includes at least one of a carbon-based material, a metal material, and a dielectric material.

The carbon-based material includes at least one of a spin-on hard mask (SOH), a spin-on organic carbon (SOC), a photoresist material (PR), and an amorphous carbon layer (ACL); and/or the metal material includes tungsten (W); and/or the dielectric material includes silicon nitride; and/or the material of the conductive structure includes at least one of NiSi, TiSi, TaSi, and CoSi, preferably NiSi.

For the formation of the filling material layer made from each of the above materials, those skilled in the art may select a corresponding known formation process according to the difference of the materials. For example, the spin-on hard mask (SOH), the spin-on organic carbon (SOC), and the photoresist material (PR) may be formed by the spin coating process, and the amorphous carbon layer (ACL), the tungsten (W), and the silicon nitride may be formed by the deposition process. The specific steps are known to those skilled in the art and will not be described here again.

In the step of removing the filling material layer, if the material of the filling material layer is at least one of the carbon-based materials such as the spin-on hard mask (SOH), the spin-on organic carbon (SOC), the photoresist material (PR), and the amorphous carbon layer (ACL), the filling material layer may be removed by ashing process; if the material of the filling material layer is a metal material such as tungsten, the filling material layer may be removed by cleaning with hydrogen peroxide; if the material of the filling material layer is a dielectric material such as silicon nitride, the filling material layer may be removed by dry etching. The specific steps of the above-mentioned removing methods are well known to those skilled in the art and will not be described here again. In the step of removing the filling material layer, the etching selectivity of the filling material layer to the conductive structure is not less than 20. Meanwhile, it may also be satisfied that in the step of removing at least the filling material layer, the etching selectivity of the filling material layer to the active pillar is not less than 20, and the etching selectivity of the filling material layer to the isolation layer is not less than 20.

In an embodiment of the present disclosure, in step S7 of the method for manufacturing a semiconductor structure, a first dielectric layer is deposited on at least side surfaces of the first grooves to form second grooves, and the first dielectric layer covers the side surfaces and the top surfaces of the conductive structures.

In an embodiment of the present disclosure, in an implementation, the dielectric constant of the first dielectric layer is smaller than that of the active pillar, the material of the first dielectric layer includes, but is not limited to, silicon oxide, silicon nitride, silicon oxynitride, carbon-doped silicon oxide, or other suitable materials, and the first dielectric layer may be carbon-doped silicon oxide in an implementation of the present disclosure; the main material of the active pillar is silicon, the dielectric constant of the silicon is 11-12, and the dielectric constant of the carbon-doped silicon oxide is about 4.5, and thus the dielectric constant of the first dielectric layer is smaller than that of the active pillar, so that the parasitic capacitance of the semiconductor structure is further reduced.

In an implementation of the present disclosure, the step of depositing the first dielectric layer at least on the side surfaces of the first grooves includes:
as shown in FIG. 3H, forming a first dielectric material layer 3011, where the first dielectric material layer 3011 covers the side surfaces and the bottom surfaces of the first grooves 201 and the top surfaces of the conductive structures 501, the first dielectric material layer 3011 serves as the first dielectric layer 301, and the second grooves 202 are formed at the same time; the first dielectric layer 301 covers the side surfaces and the top surfaces of the conductive structures 501 and the first dielectric layer plays a role in protecting the conductive structures 501.

In another implementation of the present disclosure, the step of depositing the first dielectric layer at least on the side surfaces of the first grooves includes:
as shown in FIG. 4E, forming a first dielectric material layer 3011, where the first dielectric material layer 3011 covers the side surfaces and the bottom surfaces of the first grooves 201 and the top surfaces of the conductive structures 501; and
as shown in FIG. 4F, removing the first dielectric material layer 3011 covering the bottom surfaces of the first grooves 201, where the remaining first dielectric material layer 3011 serves as the first dielectric layer 301, and the second grooves 202 are formed at the same time; the first dielectric layer 301 covers the side surfaces and the top surfaces of the conductive structures 501 and plays a role in protecting the conductive structures 501.

Specific methods for forming the first dielectric material layer 3011 include one of an atomic layer deposition (ALD) process, a plasma enhanced atomic layer deposition (PEALD) process, a chemical vapor deposition (CVD) process, and a plasma enhanced chemical vapor deposition (PECVD) process.

In an embodiment of the present disclosure, in step S8 of the method for manufacturing a semiconductor structure, a second dielectric layer is formed, and the second grooves are filled with the second dielectric layer.

In particular, the second dielectric layer may include, but is not limited to, silicon oxide, silicon nitride, silicon oxynitride, or other suitable isolation materials. In a specific implementation, the second dielectric layer is silicon oxide. Specific methods for forming the second dielectric layer include one of an atomic layer deposition (ALD) process, a plasma enhanced atomic layer deposition (PEALD) process, a chemical vapor deposition (CVD) process, and a plasma enhanced chemical vapor deposition (PECVD) process.

In an embodiment of the present disclosure, the steps of the method for manufacturing a semiconductor structure further include, after depositing the first dielectric layer and before forming the second dielectric layer:
forming a third dielectric layer, where the second grooves are filled with the third dielectric layer and the third dielectric layer covers the first dielectric layer; and
the substrate including an array region and a peripheral region, and removing the third dielectric layer in the second grooves located in the array region;
the step of forming the second dielectric layer includes forming the second dielectric layer, where the second grooves located in the array region are filled with the second dielectric layer and the second dielectric layer covers the first dielectric layer.

In particular, the third dielectric layer may include, but is not limited to, silicon oxide, silicon nitride, silicon oxynitride, or other suitable isolation materials. In a specific implementation, the third dielectric layer is silicon oxide. Specific methods for forming the third dielectric layer include one of an atomic layer deposition (ALD) process, a plasma enhanced atomic layer deposition (PEALD) process, a chemical vapor deposition (CVD) process, and a plasma enhanced chemical vapor deposition (PECVD) process.

In an implementation, as shown in FIG. 3I and FIG. 4G, a third dielectric layer 701 is formed, where the second grooves 202 are filled with the third dielectric layer 701 and the third dielectric layer covers the first dielectric layer 301;
as shown in FIG. 3J and FIG. 4H, the substrate 1 includes an array region 14 and a peripheral region 15, and the array region 14 and the peripheral region 15 are defined by a photoresist layer 801;
as shown in FIG. 3K and FIG. 4I, the third dielectric layer 701 in the second grooves 202 located in the array region 14 is removed;
as shown in FIG. 3L and FIG. 4J, the photoresist layer 801 is removed;
as shown in FIG. 3M and FIG. 4K, the step of forming the second dielectric layer 601 includes: a second dielectric layer 601 is formed, and the second grooves 202 located in the array region 14 are filled with the second dielectric layer 601 and the second dielectric layer covers the first dielectric layer 301.

Specifically, the second dielectric layer 601 may or may not have an air gap therein; preferably, in an implementation of the present disclosure, as shown in FIG. 3M and FIG. 4K, the second dielectric layer 601 has air gaps 602 therein, and in the second direction Y, the depth of the air gap 602 is greater than the thickness of the conductive structure 501; and/or
in the first direction X, the maximum width of the air gap 602 is ⅓-⅘ of the width of the second groove 202.

In an embodiment of the present disclosure, in the second direction Y, the depth of the first groove 201 is greater than the thickness of the conductive structure 501, so that it is possible that the depth of the air gap 602 in the second direction Y is greater than the thickness of the conductive structure 501. The thickness of the conductive structure refers to the depth from the top surface of the conductive structure to the bottom of the conductive structure in the second direction Y. The depth of the air gap in the second direction Y refers to the depth from the top of the air gap to the bottom of the air gap in the second direction Y. As shown in FIG. 3M and FIG. 4K, in the second direction Y, the air gap 602 has a top and a bottom. The top of the air gap 602 is higher than the top surface of the conductive structure 501, and the bottom of the air gap 602 is lower than the bottom surface of the conductive structure 501. Further, the size of the air gap 602 in the second direction Y is ⅔-⅘ of the depth of the second groove 202, and the maximum size of the air gap in the first direction X is ⅓-⅘ of the width of the second groove 202. This arrangement allows the air gap 602 to be between the conductive structures 501, thus reducing the parasitic capacitance between the conductive structures 501.

In an embodiment of the present disclosure, after the filling material layer is removed and the first grooves are exposed, the first dielectric layer and the like are formed conformally, and after the above second dielectric layer is formed, accordingly, the finally formed conductive structure 501 does not have an appearance characterized by a rounded top and a thinned waist, i.e., necking, that is, the orthographic projection of the finally formed conductive structure 501 on the surface of the substrate 1 is square; in the second direction Y, the finally formed conductive structure 501 has flat or nearly flat side surfaces (i.e., the sidewalls of the conductive structure 501 are vertical or nearly vertical). In the second direction Y, the finally formed first grooves 201 have flat or nearly flat side surfaces (i.e., the sidewalls of the first grooves 201 are vertical or nearly vertical), and the correspondingly formed first dielectric layer has flat or nearly flat side surfaces (i.e., the sidewalls of the first dielectric layer are vertical or nearly vertical); in the first direction X, the finally formed first grooves 201 have flat or nearly flat bottom surfaces (no U-shaped or V-shaped is present) and the heights of the bottom surfaces of adjacent first grooves 201 are the same or nearly the same, and the correspondingly formed first dielectric layer has a flat or nearly flat bottom surface/the formed second dielectric layer has a flat or nearly flat bottom surface.

In an embodiment of the present disclosure, the method for manufacturing a semiconductor structure further includes: as shown in FIG. 3N and FIG. 4L, forming a peripheral contact 901, where the peripheral contact 901 is directly connected to some of the conductive structures 501, the first dielectric layer 301 covers the side surfaces and parts of the top surfaces of the conductive structures directly connected to the peripheral contact 901, and the first dielectric layer 301 covers the side surfaces and all the top surfaces of the remaining conductive structures not directly connected to the peripheral contact 901. In the case of such a structure, the second dielectric layer 601 covers the corresponding parts of the first dielectric layer 301.

According to the method for manufacturing a semiconductor structure provided by the embodiments of the present disclosure, firstly, parts of the isolation layers are removed to form first grooves exposing the top surfaces and parts of the side surfaces of the active pillars; then, a filling material layer at least exposing the top surfaces of the active pillars is formed in the first grooves; next, a metal layer directly covering at least the top surfaces of the active pillars is formed, a heat treatment is performed to form conductive structures on the active pillars, respectively, and then at least the filling material layer is removed to expose the first grooves; finally, a first dielectric layer and a second dielectric layer are formed. The steps of forming first grooves first, then forming a filling material layer in the first grooves, and then removing the filling material layer after forming the conductive structures, in one aspect, make it possible to both remove parts of the isolation layers to form the first grooves and use the conductive structures as a mask to prepare the bit line in the manufacturing method; in another aspect, the steps can also prevent the appearance of the conductive structure from being changed and avoid the damage to the top and the sidewalls of the conductive structure, that is, the finally formed conductive structure can be prevented from being thinned and rounded (i.e. necking) in appearance, so that the orthographic projection of the conductive structure on the surface of the substrate is square and the conductive structure has flat or nearly flat side surfaces in the thickness direction of the substrate (i.e., the appearance of the sidewalls of the conductive structure is vertical or nearly vertical). Therefore, the resistance of the conductive structure can be reduced, the performance of the conductive structure can be improved, and the yield of the semiconductor device can be improved.

The first dielectric layer with a small dielectric constant is adopted (for example, the dielectric constant of the first dielectric layer is smaller than that of the active pillar), so that the parasitic capacitance of the semiconductor structure is further reduced. Through the above improvement, the performance and the yield of the semiconductor device can be improved.

To further reduce the parasitic capacitance, an air gap can be arranged between the conductive structures. Air has a relative dielectric constant of about 1 and can be used as a good dielectric medium to further reduce the parasitic capacitance between the conductive structures. Through the above improvement, the performance and the yield of the semiconductor device can be improved.

The present disclosure provides a semiconductor structure, as shown in FIG. 3M and FIG. 4K, which includes:
a substrate 1, where the substrate 1 is provided with active pillars 11 and isolation layers 12 arranged at intervals along a first direction X, the active pillars 11 and the isolation layers 12 all extend along a second direction Y, the first direction X is parallel to a surface of the substrate 1, the second direction Y is parallel to the thickness direction of the substrate 1, and the second direction Y is perpendicular to the first direction X;
conductive structure 501 respectively located on the active pillars 11 and connected to the active pillars 11, where the conductive structures 501 extend along a third direction Z, and the third direction Z is perpendicular to the first direction X and the second direction Y;
first grooves 201, each of the first grooves being located between adjacent conductive structures 501;
second grooves 202 respectively located in the first grooves 201;
a first dielectric layer 301 located between the first grooves 201 and the second grooves 202, where the first dielectric layer 301 covers at least side surfaces of the first grooves 201 and covers side surfaces and part of top surfaces of the conductive structures 501 (as specifically shown in FIG. 3N and FIG. 4L, the first dielectric layer 301 covers the side surfaces and part of the top surfaces of the conductive structures 501); and
a second dielectric layer 601 filling the second grooves 202.

In an implementation, as shown in FIG. 3M and FIG. 4K, in the semiconductor structure provided by the present disclosure, the substrate 1 includes an array region 14 and a peripheral region 15, and the second grooves 202 located in the array region 14 are filled with the second dielectric layer 601; the semiconductor structure further includes: a third dielectric layer 701, where the second grooves 202 in the peripheral region 15 are filled with the third dielectric layer 701.

In an implementation, the second grooves 202 located in the array region 14 are filled with the second dielectric layer 601 and the second dielectric layer covers the first dielectric layer 301.

In an implementation, the second grooves 202 located in the peripheral region 15 are filled with the third dielectric layer 701 and the third dielectric layer covers the first dielectric layer 301.

In an implementation, as shown in FIG. 3M and FIG. 4K, the second dielectric layer 601 has air gaps 602 therein, and in the second direction Y, the depth of the air gap 602 is greater than the thickness of the conductive structure 501; and/or
in the first direction X, the maximum width of the air gap 602 is ⅓-⅘ of the width of the second groove 202.

In an implementation, the depth of the first groove 201 is greater than the thickness of the conductive structure 501 in the second direction Y. The thickness of the conductive structure refers to the depth from the top surface of the conductive structure to the bottom of the conductive structure in the second direction Y. The depth of the air gap in the second direction Y refers to the depth from the top of the air gap to the bottom of the air gap in the second direction Y. As shown in FIG. 3M and FIG. 4K, in the second direction Y, the air gap 602 has a top and a bottom. The top of the air gap 602 is higher than the top surface of the conductive structure 501, and the bottom of the air gap 602 is lower than the bottom surface of the conductive structure 501. Further, the size of the air gap 602 in the second direction Y is ⅔-⅘ of the depth of the second groove 202, and the maximum size of the air gap in the first direction X is ⅓-⅘ of the width of the second groove 202. This arrangement allows the air gap 602 to be between the conductive structures 501, thus reducing the parasitic capacitance between the conductive structures 501.

In an implementation, as shown in FIG. 3M and FIG. 4K, the dielectric constant of the first dielectric layer 301 is smaller than that of the active pillar, the material of the first dielectric layer 301 includes, but is not limited to, silicon oxide, silicon nitride, silicon oxynitride, carbon-doped silicon oxide, or other suitable materials, and the first dielectric layer 301 may be carbon-doped silicon oxide in an implementation of the present disclosure; the main material of the active pillar is silicon, the dielectric constant of the silicon is 11-12, and the dielectric constant of the carbon-doped silicon oxide is about 4.5, and thus the dielectric constant of the first dielectric layer 301 is smaller than that of the active pillar, so that the parasitic capacitance of the semiconductor structure is further reduced. The resistivity of the conductive structure is not more than 20 μΩ·cm, and the material of the conductive structure may be NiSi. For other similar or corresponding parts, reference may be made to the corresponding descriptions in the foregoing embodiments of the method for manufacturing a semiconductor structure, which are not described here again.

In an implementation, as shown in FIG. 3M and FIG. 4K, the orthographic projection of the conductive structure 501 on the surface of the substrate 1 is square; and/or
in the second direction Y, the conductive structure 501 has flat or nearly flat side surfaces; and/or
in the second direction Y, the first groove 201 has flat or nearly flat side surfaces; and/or
in the first direction X, the first groove 201 has a flat or nearly flat bottom surface (no U-shaped or V-shaped bottom is present) and the heights of the bottom surfaces of adjacent first grooves 201 are the same or nearly the same.

In an implementation, as shown in FIG. 3N and FIG. 4L, the semiconductor structure provided by the present disclosure further includes a peripheral contact 901, where the peripheral contact 901 is directly connected to some of the conductive structures 501, the first dielectric layer 301 covers the side surfaces and parts of the top surfaces of the conductive structures 501 directly connected to the peripheral contact 901, and the first dielectric layer 301 covers the side surfaces and all the top surfaces of the remaining conductive structures not directly connected to the peripheral contact 901. It will be appreciated that illustratively, only one peripheral contact 901 is shown in FIG. 3N and FIG. 4L, and other peripheral contacts are not shown. In the case of such a structure, the second dielectric layer 601 covers the corresponding parts of the first dielectric layer 301.

Specifically, it will be appreciated by those skilled in the art that the second grooves 202 are filled with the second dielectric layer 601 and the second dielectric layer 601 covers the first dielectric layer 301. That is, the first dielectric layer 301 and the second dielectric layer 601 cover the side surfaces and parts of the top surfaces of the conductive structures 501 directly connected to the peripheral contact 901, and the first dielectric layer 301 and the second dielectric layer 601 cover the side surfaces and all the top surfaces of the remaining conductive structures not directly connected to the peripheral contact 901.

Specifically, it will be appreciated by those skilled in the art that the third dielectric layer 701 covers the above first dielectric layer 301.

Further, it will be appreciated by those skilled in the art that compared with FIG. 3M, FIG. 3N has an added peripheral contact 901, the first dielectric layer 301 and the second dielectric layer 601 cover the side surfaces and parts of the top surfaces of the conductive structures 501 directly connected to the peripheral contact 901, the first dielectric layer 301 and the second dielectric layer 601 cover the side surfaces and all the top surfaces of the remaining conductive structures not directly connected to the peripheral contact 901, and none of the other structures are changed, and when referring to FIG. 3N, for structures that are not shown by reference numerals in FIG. 3N, reference may be made to the corresponding structures that have been shown by reference numerals in FIG. 3M; similarly, compared with FIG. 4K, FIG. 4L has an added peripheral contact 901, the first dielectric layer 301 and the second dielectric layer 601 cover the side surfaces and parts of the top surfaces of the conductive structures 501 directly connected to the peripheral contact 901, the first dielectric layer 301 and the second dielectric layer 601 cover the side surfaces and all the top surfaces of the remaining conductive structures not directly connected to the peripheral contact 901, and none of the other structures are changed, and when referring to FIG. 4L, for structures that are not shown by reference numerals in FIG. 4L, reference may be made to the corresponding structures that have been shown by reference numerals in FIG. 4K.

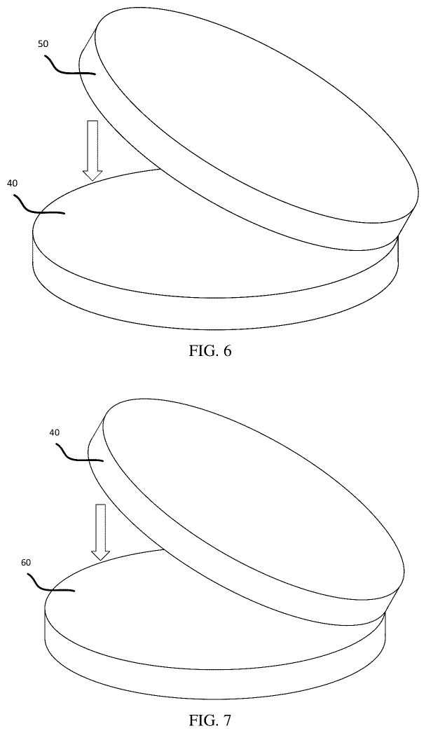

FIG. 5 is a schematic structural diagram of a semiconductor structure of the present disclosure in another implementation. As shown in FIG. 5, on the basis of the semiconductor structure shown in FIG. 3N, the substrate further includes word line structures 10; the word line structure 10 is disposed around the active pillar 11, the active pillars 11 are disposed at intervals along both the first direction X and the third direction Z, and the active pillars 11 are isolated from each other by the isolation layer 12; one end of the active pillar 11 is electrically connected to the conductive structure 501, the conductive structure 501 may be a bit line structure, the other end of the active pillar 11 is electrically connected to a capacitor structure 20, and adjacent capacitor structures are isolated from each other by a fourth dielectric layer 30. The semiconductor structure in this embodiment may be a gate-all-around (GAA) structure or a vertical channel transistor (VCT) structure.

In another implementation, compared with FIG. 5, the first dielectric layer 301 covers only the side surfaces of the first groove 201 and does not cover the bottom surface of the first groove 201, and the other structures are the same as FIG. 5, and the structure shown in this implementation is not shown in the drawings.

The conductive structure of the semiconductor structure of the present disclosure does not become thinned and rounded in appearance (i.e., necking), such that the orthographic projection of the conductive structures on the surface of the substrate is square and has flat or near flat side surfaces in the second direction (i.e., the appearance of the sidewalls of the conductive structure is vertical or nearly vertical). Therefore, the resistance of the conductive structure can be reduced, the performance of the conductive structure can be improved, and the yield of the semiconductor device can be improved.

In an implementation, in the semiconductor structure of the present disclosure, the first dielectric layer with a small dielectric constant is adopted (for example, the dielectric constant of the first dielectric layer is smaller than that of the active pillar), so that the parasitic capacitance of the semiconductor structure is further reduced. Through the above improvement, the performance and the yield of the semiconductor device can be improved.

In an implementation, an air gap is arranged between the conductive structures. Air has a relative dielectric constant of about 1 and can be used as a good dielectric medium to further reduce the parasitic capacitance between the conductive structures. Through the above improvement, the performance and the yield of the semiconductor device can be improved.

FIG. 6 is a schematic structural diagram of a memory device formed by bonding the wafer having the semiconductor structure of the present disclosure to one wafer. FIG. 7 is a schematic structural diagram of a memory device formed by bonding the wafer having the semiconductor structure of the present disclosure to another wafer.

As shown in FIG. 6, the memory device includes a first wafer 40 and a second wafer 50. The first wafer 40 has the semiconductor structure of the present disclosure described above (the first wafer 40 may be an array wafer), the second wafer 50 includes a control circuit (the second wafer 50 may be a CMOS wafer), and the first wafer 40 and the second wafer 50 are bonded to form the memory device.

In an implementation, the back side of the first wafer 40 and the second wafer 50 may be bonded by hybrid bonding to form the memory device.

As shown in FIG. 7, the memory device includes a first wafer 40 and a third wafer 60. The first wafer 40 has the semiconductor structure of the present disclosure described above (the first wafer 40 may be an array wafer), the third wafer 60 may be a carrier wafer, and the first wafer 40 and the third wafer 60 are bonded to form the memory device.

In an implementation, the front side of the first wafer 40 and the third wafer 60 may be bonded by fusion bonding to form the memory device.

It will be appreciated by those skilled in the art that the memory device may be formed by bonding the front side of the first wafer 40 to the third wafer 60 and then bonding the back side of the first wafer 40 to the second wafer 50.

Those of ordinary skill in the art can understand that the foregoing implementations are specific embodiments of practicing the present disclosure, while in practical application, various changes can be made to the implementations in form and detail without departing from the spirit and scope of the present disclosure. Any person skilled in the art can make various changes and modifications without departing from the spirit and scope of the present disclosure, and the protection scope of the present disclosure is defined by the appended claims.

1. A method for manufacturing a semiconductor structure, comprising:
providing a substrate, wherein the substrate is provided with active pillars and isolation layers arranged at intervals along a first direction, the active pillars and the isolation layers all extend along a second direction, the first direction is parallel to a surface of the substrate, the second direction is parallel to a thickness direction of the substrate, and the second direction is perpendicular to the first direction;
removing parts of the isolation layers to form first grooves, wherein the first grooves expose top surfaces and parts of side surfaces of the active pillars;
forming a filling material layer in the first grooves, wherein the filling material layer exposes at least the top surfaces of the active pillars;
forming a metal layer, wherein the metal layer directly covers at least the top surfaces of the active pillars;
performing a heat treatment to form conductive structures on the active pillars, respectively, wherein the conductive structures extend along a third direction, and the third direction is perpendicular to the first direction and the second direction;
removing at least the filling material layer to expose the first grooves;
depositing a first dielectric layer at least on side surfaces of the first grooves to form second grooves, wherein the first dielectric layer covers side surfaces and top surfaces of the conductive structures; and
forming a second dielectric layer, wherein the second grooves are filled with the second dielectric layer.

2. The manufacturing method according to claim 1, wherein in the step of forming the filling material layer in the first grooves, in the second direction, a height of a top surface of the filling material layer is controlled to be not lower than a height at which 50% of a thickness of each of the conductive structures is present, and the filling material layer exposes the top surfaces of the active pillars.

3. The manufacturing method according to claim 2, wherein the step of forming the filling material layer in the first grooves comprises:
forming an initial filling material layer in the first grooves, wherein the first grooves are filled with the initial filling material layer and the initial filling material layer covers the top surfaces of the active pillars; and
removing at least the initial filling material layer covering the top surfaces of the active pillars such that in the second direction, a height of a top surface of the initial filling material layer that remains is not lower than the height at which 50% of the thickness of the conductive structure is present, wherein the initial filling material layer that remains serves as the filling material layer; or
forming an initial filling material layer in the first grooves such that in the second direction, a height of a top surface of the initial filling material layer is not lower than the height at which 50% of the thickness of the conductive structure is present, and the initial filling material layer exposes the top surfaces of the active pillars, wherein the initial filling material layer serves as the filling material layer.

4. The manufacturing method according to claim 1, wherein in the step of removing at least the filling material layer, an etching selectivity of the filling material layer to the conductive structures is not less than 20.

5. The manufacturing method according to claim 4, wherein a material of the filling material layer comprises at least one of a carbon-based material, a metal material, and a dielectric material, wherein the carbon-based material comprises at least one of a spin-on hard mask, a spin-on organic carbon, a photoresist material, and an amorphous carbon layer; the metal material comprises tungsten; the dielectric material comprises silicon nitride; and a material of the conductive structures comprises at least one of NiSi, TiSi, TaSi, and CoSi.

6. The manufacturing method according to claim 1, wherein the step of depositing the first dielectric layer at least on the side surfaces of the first grooves comprises:
forming a first dielectric material layer, wherein the first dielectric material layer covers the side surfaces and bottom surfaces of the first grooves and the top surfaces of the conductive structures, and the first dielectric material layer serves as the first dielectric layer; or
forming a first dielectric material layer, wherein the first dielectric material layer covers the side surfaces and bottom surfaces of the first grooves and the top surfaces of the conductive structures; and
removing the first dielectric material layer covering the bottom surfaces of the first grooves, and the first dielectric material layer that remains serves as the first dielectric layer.

7. The manufacturing method according to claim 1, wherein after depositing the first dielectric layer and before forming the second dielectric layer, the manufacturing method further comprises:
forming a third dielectric layer, wherein the second grooves are filled with the third dielectric layer and the third dielectric layer covers the first dielectric layer; and
the substrate comprising an array region and a peripheral region, and removing the third dielectric layer in the second grooves located in the array region;
the step of forming the second dielectric layer comprises: forming the second dielectric layer, wherein the second grooves located in the array region are filled with the second dielectric layer and the second dielectric layer covers the first dielectric layer.

8. The manufacturing method according to claim 1, wherein in the second direction, a depth of each of the first grooves is greater than the thickness of the conductive structure.

9. The manufacturing method according to claim 1, wherein the second dielectric layer has air gaps therein, and in the second direction, a depth of each of the air gaps is greater than the thickness of the conductive structure.

10. The manufacturing method according to claim 9, in the first direction, a maximum width of the air gap is ⅓-⅘ of a width of each of the second grooves.

11. The manufacturing method according to claim 1, wherein an orthographic projection of the conductive structure on the surface of the substrate is square;
in the second direction, the conductive structure has flat or nearly flat side surfaces;
in the second direction, the first grooves exposed after removal of the filling material layer have flat or nearly flat side surfaces; and
in the first direction, the first grooves exposed after removal of the filling material layer have flat or nearly flat bottom surfaces and heights of the bottom surfaces of adjacent first grooves are the same or nearly the same.

12. A semiconductor structure, comprising:
a substrate provided with active pillars and isolation layers arranged at intervals along a first direction, wherein the active pillars and the isolation layers all extend along a second direction, the first direction is parallel to a surface of the substrate, the second direction is parallel to a thickness direction of the substrate, and the second direction is perpendicular to the first direction;
conductive structures respectively located on the active pillars and connected to the active pillars, wherein the conductive structures extend along a third direction, and the third direction is perpendicular to the first direction and the second direction;
first grooves, each of the first grooves being located between adjacent conductive structures;
second grooves respectively located in the first grooves;
a first dielectric layer located between the first grooves and the second grooves, the first dielectric layer covering at least side surfaces of the first grooves and covering side surfaces and part of top surfaces of the conductive structures; and
a second dielectric layer filling the second grooves.

13. The semiconductor structure according to claim 12, wherein the substrate comprises an array region and a peripheral region, and the second grooves located in the array region are filled with the second dielectric layer; the semiconductor structure further comprises:
a third dielectric layer, the second grooves located in the peripheral region being filled with the third dielectric layer.

14. The semiconductor structure according to claim 12, wherein in the second direction, a depth of the first groove is greater than a thickness of each of the conductive structures.

15. The semiconductor structure according to claim 12, wherein the second dielectric layer has air gaps therein, and in the second direction, a depth of each of the air gaps is greater than the thickness of each of the conductive structures.

16. The semiconductor structure according to claim 15, in the first direction, a maximum width of the air gap is ⅓-⅘ of a width of each of the second grooves.

17. The semiconductor structure according to claim 12, wherein an orthographic projection of each of the conductive structures on the surface of the substrate is square.

18. The semiconductor structure according to claim 12, in the second direction, the conductive structure has flat or nearly flat side surfaces.

19. The semiconductor structure according to claim 12, in the second direction, the first groove has flat or nearly flat side surfaces.

20. The semiconductor structure according to claim 12, in the first direction, the first groove has a flat or nearly flat bottom surface and heights of the bottom surfaces of adjacent first grooves are the same or nearly the same.
